(19) United States
(12) Patent Application Publication
(10) Pub. No.: US 2006/0138939 A1
(43) Pub. Date: Jun. 29, 2006

(54) Light emissive device

(75) Inventor: Matthew Roberts, Cambridge (GB)

Correspondence Address: MARSHALL, GERSTEIN & BORUN LLP, 233 S. WACKER DRIVE, SUITE 6300, SEARS TOWER, CHICAGO, IL, 60606, US

(73) Assignee: CAMBRIDGE DISPLAY TECHNOLOGY LIMITED, Cambridgeshire (GB)

(21) Appl. No.: 11/300,832

(22) Filed: Dec. 15, 2005

(30) Foreign Application Priority Data
Dec. 24, 2004 (GB) 0428409.7

(51) Int. Cl. H01L 51/50; H05B 33/28

(52) U.S. Cl. 313/503; 313/506; 428/690; 428/457; 428/917; 427/66; 313/113; 257/89; 257/E51.022

(57) ABSTRACT

An organic light emissive device including a cathode; an anode; and an organic light emissive region between the cathode and the anode, wherein the cathode includes a transparent bilayer comprising a layer of a low work function metal having a work function of no more than 3.5 eV and a transparent layer of silver.

### BACKGROUND OF THE INVENTION

1. Field of the Invention

The invention relates generally to organic light emissive devices, to methods of making such devices, and to the use of cathodes therein.

2. Description of Related Technology

Organic light emissive devices (OLEDs) generally include a cathode, an anode and an organic light emissive region between the cathode and the anode. Light emissive organic materials may contain small molecular materials such as described in U.S. Pat. No. 4,539,507 or polymeric materials such as those described in WO 90/13148. The cathode injects electrons into the light emissive region and the anode injects holes. The electrons and holes combine to generate photons.

FIG. 1 shows a typical cross-sectional structure of an OLED. The OLED is typically fabricated on a glass or plastic substrate 1 coated with a transparent anode 2 such as an indium-tin-oxide (ITO) layer. The ITO coated substrate is covered with at least a layer of a thin film of an electroluminescent organic material 3 and a layer of cathode material 4 of low workfunction metal such as calcium is applied, optionally with a capping layer of aluminum (not shown). Other layers may be added to the device, for example to improve charge transport between the electrodes and the electroluminescent material.

There has been a growing interest in the use of OLEDs in display applications because of their potential advantages over conventional displays. OLEDs have relatively low operating voltage and power consumption and can be easily processed to produce large area displays. On a practical level, there is a need to produce OLEDs which are bright and operate efficiently but which are also reliable to produce and stable in use.

The structure of the cathode in OLEDs is one aspect under consideration in this art. In the case of a monochrome OLED, the cathode may be selected for optimal performance with the single electroluminescent organic material. However, a full color OLED comprises red, green and blue light organic emissive materials. Such a device requires a cathode capable of injecting electrons into all three emissive materials, i.e. a “common electrode.” A variety of cathode configurations have been proposed, each of which involves an additional layer to improve electron injection. For example, it is known from Applied Phys. Let. 70, 150, 1997 that a layer of metal fluoride located between the organic emissive layer and the metal cathode can result in an improvement in device efficiency. LiF/Al cathodes are proposed in Applied Phys. Lett. 97 (5), 563-565, 2001. Other arrangements are found in Synth. Metals 2000, 111-112, p125-128 and WO 03/019696. A light absorbent cathode maybe formed of LiF optionally codeposited with A1 for use as an electron-injecting layer according to WO 00/35028. U.S. Pat. No. 6,278,236 also provides a multilayer organic electroluminescent device with an electron-injecting layer. In this arrangement, the electron-injecting layer includes aluminum and at least one alkali metal halide or at least one alkaline earth metal halide. A composite electron-injecting layer comprising lithium fluoride and aluminum is exemplified. Another composite cathode is described in Jabbour et al in Applied Phys. Letts. 73 (9), 1185-1187 (1998). US 2001/0051284A also describes a composite electron-injection layer in a multilayer organic electroluminescent device. A reflecting cathode using a layer of aluminum or silver is described in Applied Phys. Lett 85(13), 2469-2471 (2004). A (semi)transparent layer of silver is used as an anode.

In certain device applications it is necessary for the cathode to be transparent. This is particularly the case where drive circuitry or other structures are situated adjacent to the anode thereby preventing light emission through the anode. These devices are frequently termed “top emitting devices”. FIG. 2 shows in diagrammatic form a typical cross-sectional structure of a top emitting OLED. An anode material 22 such as ITO may be situated on a metal mirror 25 which is positioned over an active matrix back plane 21. A layer of hole transporting material 26 is situated between the anode 22 and an emissive layer 23. Optionally, a further intermediate layer 27 may be applied between the electron-injection layer and the light emitting layer.

In this arrangement, cathode layer 24 is situated over the light emitting layer 23 and is generally a layer of barium, which is a low work function metal so as to be able to inject electrons into the emissive layer. A buffer layer 28 is deposited over the barium cathode layer 24 and an indium tin oxide (ITO) layer 29 is sputtered over the buffer layer to provide a relatively transparent layer of lateral conductivity to compensate for the relatively low conductivity of the barium cathode. Finally, a transparent encapsulation layer (not shown) is applied over the ITO layer so as to protect the device from ingress of oxygen and moisture. In this arrangement, the buffer layer 28 is generally a dielectric layer. According to the Journal of Applied Physics 94(8), 5290-5296 (2004), dielectric layers of this type can modulate the transmittance of the cathode and achieve a significant improvement in light output. However, the need to sputter an ITO layer over the dielectric layer can lead to cathode damage.

Other transparent cathode arrangements have been proposed, such as those exemplified in WO 04/0708045. These include a trilayer arrangement of barium fluoride or lithium fluoride with calcium and gold, as well as arrangements involving the use of aluminum. On a practical level, aluminum has been the material of choice and transparent cathodes involving a bilayer of barium and aluminum have been successfully produced by the applicants. Aluminum is particularly useful as a conductive layer which also acts to protect the barium. The barium is useful as an electron-injecting material which interacts well with light emissive layers.

### GENERAL DESCRIPTION OF THE INVENTION

The present invention provides an organic light emissive device with improved properties, including a cathode which does not suffer from the drawbacks of cathode structures of the prior art.

In a first aspect, the invention provides an organic light emissive device including a cathode;
an anode; and
an organic light emissive region between the cathode and the anode, wherein the cathode includes a transparent bilayer comprising a layer of a low work function metal having a work function of no more than 3.5 eV and a transparent layer of silver.

In accordance with the invention, it has been surprisingly found that a cathode includes a transparent bilayer of a low work function metal and a transparent layer of silver may improve the transmission of the cathode and improve the reproducibility and reliability of the cathode in the manufacture of transparent cathode devices.

The low work function metal of the bilayer is preferably an alkali metal or an alkaline earth metal. Of the alkaline earth metals, magnesium and beryllium have work functions which are too high for use in the present invention. Radium is not a preferred choice being impractical to use on account of its radioactive half life. Calcium and barium are preferred as the low work function metal. Of the alkali metals, lithium is preferred. The low work function metal has a work function of no more than 3.5 eV, preferably no more than 3.2 eV and more preferably no more than 3 eV. The low work function metal may have a work function as low as 2 eV, however its work function is most preferably in the range 2.5-3 eV. Under certain conditions, the low work function metal may be provided as a low work function metal compound or alloy which provides a source of low work function metal in the bilayer. Barium is particularly preferred as the low work function metal.

Depending on the transparency of the bilayer, this preferably has a thickness of 5 nm to 20 nm, alternatively from 5 nm to 10 nm, more preferably from 7 nm to 15 nm, and most preferably around 10 nm. The transparency of the bilayer depends on the thickness and the composition thereof, particularly thickness of the transparent silver layer. The silver layer may have a thickness in the range of from 2 nm to 18 nm. Additionally, physical or chemical interactions between the components of the bilayer may have an effect on its transparency. Preferably, the transparency of the bilayer in the device is at least 60%, more preferably at least 65%, still more preferably at least 80%, and most preferably at least 90%. The transparent silver layer typically has a transparency of at least 70%, preferably at least 80%, more preferably at least 90%, and most preferably at least 95%.

It is particularly preferred that the transparency ranges set out above are met across all of the visible wavelength, typically 400 to 700 nm. This is readily achievable with the use of silver in the bilayer because the optical transmittance of silver across the visible range varies insignificantly.

Where the organic light emissive device is a top-emitting device, little or no light emission would be expected or desired through the anode. In one arrangement, the anode is provided on a substrate including a metal mirror typically configured to reflect light emitted from the emissive layer out of the device through the cathode. An active matrix back plane may be provided at the other side of the substrate. In an alternative embodiment, a transparent anode is used in conjunction with the cathode of the invention.

Because the bilayer of the invention is capable of injecting electrons into red, green and blue light emitting materials, the cathode may be used as a “common cathode” in an organic light emissive device. According to this aspect of the invention there is provided an organic light emissive device in which the organic light emissive region includes discrete sub-pixels of red, green and blue light emitting materials. The cathode injects electrons into each sub-pixel. In this way there is no need for separate cathodes to inject electrons into each sub-pixel separately. This greatly simplifies construction of multicolor organic light emissive devices. The construction of multicolor and full color displays with a common cathode will be apparent to the skilled person. For example, an inkjet printed full color display is disclosed in Synth. Metals 2000, 111-112, p.125-128.

Optionally, the cathode further includes an encapsulanting layer of SiO₂ or ZnS in electrical contact with the side of the bilayer furthest from the emissive region. In this arrangement, the device may be encapsulated to prevent entering of moisture and oxygen. Other suitable encapsulants include a sheet of glass, films having suitable barrier properties such as alternating stacks of polymer and dielectric as disclosed in, for example, WO 01/81649, the disclosure of which is incorporated herein by reference or an airtight container as disclosed in, for example, WO 01/19142 the disclosure of which is incorporated herein by reference. A getter material for absorption of any atmospheric moisture and / or oxygen that may permeate through the substrate or encapsulant may be disposed between the substrate and the encapsulant.

The anode may be constructed of any suitable material and typically has a work function greater than 4.3 eV, usually around 4.8 eV. Suitable anode materials include tin oxide, high work function metals such as gold or platinum and indium tin oxide (ITO). Indium tin oxide is preferred. Other materials include chromium and alloys of chromium and nickel.

The organic light emissive region may contain any suitable organic light emitting material such as an electroluminescent polymer, an electroluminescent dendrimer, an electroluminescent small molecule, or any combination thereof which is electroluminescent. The organic light emitting material is typically applied or formed as a layer thereof.

Small molecule electroluminescent materials include 8-hydroxy quinoline aluminum (alq3 as described in U.S. Pat. No. 4,539,507). These materials are typically deposited as an organic thin film in OLEDs. Other small molecule emitters may be deposited in a host material which is usually polymeric, as part of a host-dopant system as disclosed in, for example, J. Appl. Phys. 1989, 65(9), 3610-3616, the disclosure of which is incorporated herein by reference.

Electroluminescent polymers include those described in WO 90/13148, the disclosure of which is incorporated herein by reference, such as polyarylene vinylenes, including poly(para-phenylene vinylene) (PPV). Other materials include poly(2-methoxy-5(2′-ethyl)hexyloxyphenylene-vinylene) (“MEH-PPV”), one or more PPV-derivatives (e.g. di-alkoxy or di-alkyl derivatives), polyfluorenes and/or co-polymers incorporating polyfluorene segments, PPVs and related co-polymers, poly(2,7-(9,9-di-n-octylfluorene) (“F8”), poly(2,7-(9,9-di-n-octylfluorene)-(1,4-phenylene -((4-secbutylphenyl)imino)-1,4-phenylene)) (“F8-TFB”), poly(2,7-(9,9-di-n-octylfluorene) -1,4-phenylene-((4-methylphenyl)imino)-1,4-phenylene-((4-methylphenyl) imino)-4-phenylene)) (“F8-PFM”), poly(2,7-(9,9-di-n-octylfluorene) -(1,4-phenylene-((4-methoxyphenyl)imino)- 1,4-phenylene-((4- methoxyphenyl) imino)-1,4-phenylene)) (“F8-PFMO”), or (2,7-(9,9-di-n-octylfluorene) -3,6-Benzothiadiazole) (“F8BT”).

Methods of forming layers of these polymers in OLEDs are well known in this art.

Electroluminescent dendrimers are also known for use in organic emissive layers in OLEDs. Such dendrimers preferably have the formula:
CORE−[DENDRITE]ₙ

in which CORE represents a metal cation or a group containing a metal ion, n represents an integer of 1 or more, each DENDRITE, which may be the same or different represents an inherently at least partially conjugated dendritic structure comprising aryl and/or heteroaryl groups or nitrogen and, optionally, vinyl or acetylenyl groups connected via sp or sp hybridised carbon atoms of said (hetero)aryl vinyl and acetylenyl groups or via single bonds between N and (hetero)aryl groups, CORE terminating in the single bond which is connected to an sp hybridised (ring) carbon atom of the first (hetero)aryl group or single bond to nitrogen to which more than one at least partly conjugated dendritic branch is attached, said ring carbon or nitrogen atom forming part of said DENDRITE.

Emission is typically provided by the dendrimer core; emission may be fluorescent as disclosed in WO 99/21935 or phosphorescent as disclosed in WO 02/066552.

Optionally the organic light emissive device may include a hole transporting layer between the anode and the organic light emissive region. Such a layer may assist hole injection from the anode into the emissive region. Examples of organic hole injection materials include PEDT/PSS as disclosed in EP 901 176 and EP 947 123, or polyarylene as disclosed in U.S. Pat. No. 5,723,873 and U.S. Pat. No. 5,798,170. PEDT/PSS is polystyrene sulphonic acid doped polyethylene dioxythiophene. Other hole transporting materials include PPV and poly(2,7-(9,9-di-n-oxtylfluorene)-(1,4-phenylene-(4-imino(benzoic acid))-1,4-phenylene-(4-imino(benzoic acid))-1,4-phenylene)) (BFA) and polyaniline.

In a further aspect, the invention provides a process for the manufacture of an organic light emissive device as defined above, including the steps of:

providing a portion of the device, which portion includes an anode and an organic light emissive region;

depositing a layer of a low work function metal having a work function of no more than 3.5 eV; and

depositing a transparent silver layer to form a transparent bilayer on the organic light emissive region.

### BRIEF DESCRIPTION OF THE DRAWINGS

The invention will now be described in further detail, by way of example only, with reference to the accompanying drawings in which:

FIG. 1 shows in diagrammatic form a typical cross-sectional structure of an OLED;

FIG. 2 shows in diagrammatic form a typical cross-sectional structure of a top emitting OLED;

FIG. 3 shows in diagrammatic form a cross-sectional structure of an OLED according to the invention;

FIGS. 4a and 4b show respectively plots of transmission vs Ba/Al and Ba/Ag for light at 633 nm;

FIG. 5 shows a plot of transmission vs wavelength for Ba/Al and Ba/Ag cathodes; and

FIG. 6 shows a plot of transparency vs resistance for Ba/Ag cathodes as compared with Ba/Al cathodes.

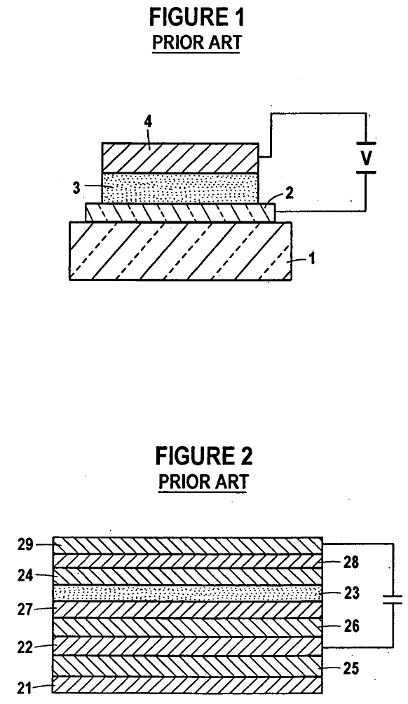

### DETAILED DESCRIPTION

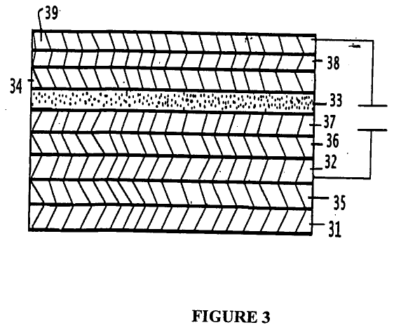

FIG. 3 shows in diagrammatic form a cross-sectional structure of a top emitting OLED according to the invention. An anode material 32 such as ITO may be situated on a metal mirror 35 which is positioned over an active matrix back plane 31.

A layer hole transporting material 36 is PEDT/PSS and is situated between the anode 32 (ITO) and an emissive layer 33. Optionally, a further intermediate layer 37 may be applied between the electron-injecting layer and the light emitting layer.

A low work function metal (Ba) layer 34 is deposited over the light emitting layer 33 by electron beam evaporation or thermal evaporation. Over this layer is deposited a silver layer 38, also by electron beam evaporation or thermal evaporation. Optionally, SiO₂ or ZnS is deposited over the silver layer to form a transparent encapsulation layer so as to protect the device from ingress of oxygen and moisture. The encapsulation layer is generally a dielectric or polymer-dielectric composition.

Transparency Measurement

According to a first measurement technique, the bilayer is deposited onto a cleaned 0.7 mm blank glass substrate by evaporation of each layer. Following evaporation, the substrate is transferred to a glove box associated with the evaporation apparatus to avoid any exposure of the oxygen and moisture-sensitive Ba metal to the atmosphere.

Transparency of the bilayer on glass is measured in the glove box using a He-Ne 635 nm laser diode and silicon photodiode detector. Transparency of the blank glass is also measured and transparency of the bilayer alone is calculated as a ratio by dividing the transparency of the bilayer on glass by the transparency of the blank glass.

According to a second measurement technique, the first measurement technique is followed except that a layer of silicon dioxide is evaporated over the bilayer in order to further minimize any exposure of the bilayer to oxygen or moisture, and transparency of a layer of silicon dioxide on glass is measured instead of transparency of blank glass for the purpose of the ratio calculation.

Device Fabrication

### EXAMPLE 1

### Blue Device

Poly(ethylene dioxythiophene) / poly(styrene sulfonate) (PEDT / PSS), available from H C Starck of Leverkusen, Germany as Baytron P® is deposited over an indium tin oxide anode supported on a glass substrate (available from Applied Films, Colorado, USA) by spin coating. A hole transporting layer of F8-TFB (shown below) is deposited over the PEDT / PSS layer by spin coating from xylene solution to a thickness of about 10 nm and heated at 180° C. for one hour. A blue electroluminescent polymer as disclosed in WO 03/095586 is deposited over the layer of F8-TFB by spin-coating from xylene solution to form an electroluminescent layer having a thickness of around 65 nm. A 5 nm thick layer of Ba is formed over the electroluminescent layer by evaporation of Ba until the desired thickness is reached.

A 5 nm thick layer of Ag is then similarly formed over the Ba layer. Finally, the device is sealed from the atmosphere by placing a glass plate over the device such that the device is located within a cavity formed within the center of the glass plate and gluing the glass plate to the substrate.

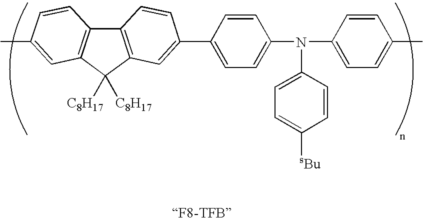

In order to maximise light output through the cathode, a reflective layer may also be provided on the substrate.

### EXAMPLE 2

### Red Device

Devices may be prepared in accordance with the process of Example 1, except that the electroluminescent layer is formed from a red electroluminescent polymer comprising 50 mol % 9,9-di-n-octylfluorene-2,7-diyl, 17 mol % “TFB” repeat units (illustrated below), 30 mol % 1,3,2-benzothiadiazole-4,7-diyl, and 3 mol % 4,7-bis(2-thiophen-5-yl) -1,3,2-benzothiadiazole. Materials of this type are disclosed in WO 00/46321 and WO 00/55927.

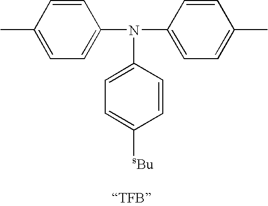

### EXAMPLE 3

### Green Electroluminescent Device

Devices may be prepared in accordance with the process of Example 1, except that the electroluminescent layer is formed from a green electroluminescent polymer as disclosed in, for example, WO 00/55927 and WO 00/46321.

### EXAMPLE 4

### Full Color Device

A full color device may be prepared according to the method of Example 1 except that the PEDT / PSS and F8-TFB layers are deposited by inkjet printing into inkjet wells formed by photolithography defining red, green and blue subpixel areas followed by inkjet printing the aforementioned red, green and blue electroluminescent polymers

### EXAMPLE 5

### Comparison Between Ba/Al and Ba/Ag Cathodes

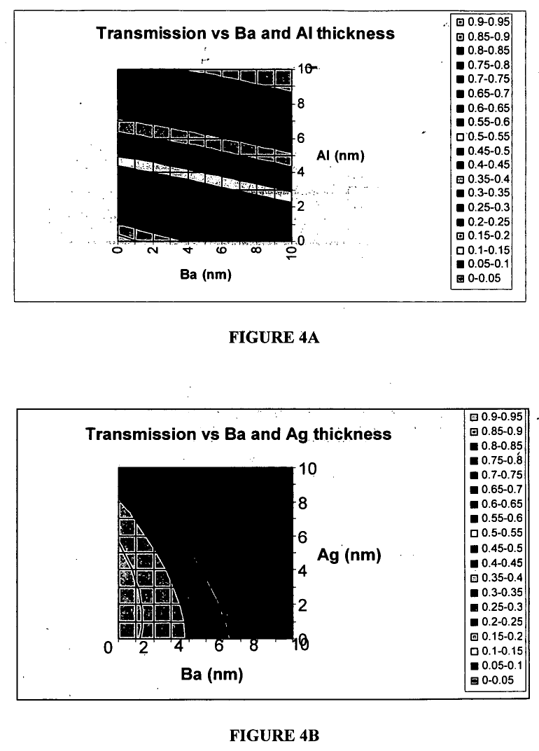

FIG. 4a shows a plot of transmission vs thickness of Ba and Al. This illustrates how sensitive transmission of light through the cathode is to Al thickness. If the minimum acceptable Ba thickness is taken to be 5 nm, this plot indicates that Al must be kept below 1 nm to keep the transmission above 75%. Each additional nm of aluminum thickness drops the transmission by an additional 5% approximately. FIG. 4b shows an analogous plot replacing the Al with Ag. According to this plot, silver thicknesses of up to 7 nm give an acceptable transmission of 75%. The transmission is much more tolerant to small changes in the thickness of Ag as compared to that of Al.

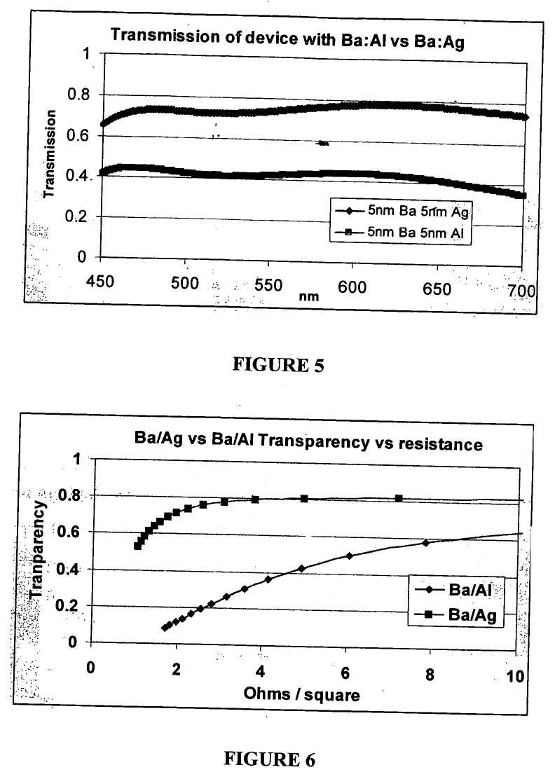

The results in FIGS. 4a and 4b were obtained for light at the red end of the visible spectrum (633 nm). FIG. 5 shows the difference between transmission of a device with a Ba:Al cathode compared to one with a Ba:Ag cathode. In each case, the cathode has a bilayer, each component of which having a layer thickness of 5 nm. The Figure demonstrates that significantly greater light transmission across the entire visible range may be achieved using a Ba:Ag cathode. This demonstrates the suitability of such cathodes for full color displays and their potential for use as common cathodes.

FIG. 6 shows a plot of transparency vs resistance for Ba/Ag cathodes as compared with Ba:Al cathodes. It will be apparent from this Figure that a Ba:Al cathode can give a suitable combination of transparency and resistance whereas the Ba:Al system suffers from low transmission and moderate resistance.

Devices according to the invention therefore use silver to provide full cathode transparency control over achievable and sensible thickness ranges. This allows tuning of the cavity strength to suit different device requirements such as color gamut, angular color shift and outcoupling efficiency. Thicker metal capping layers may be used to achieve adequate transparency and this may provide more protection for the underlying light emissive layers if further layer deposition is required. By allowing a greater metal thickness for a given transparency, there is a greater tolerance during manufacture to errors in cathode thickness for achieving a desired transparency.

1.-13. (canceled)

14. An organic light emissive device comprising:
a cathode;
an anode; and
an organic light emissive region between the cathode and the anode,
wherein the cathode comprises a transparent bilayer comprising a layer of a low work function metal having a work function of no more than 3.5 eV and a transparent layer of silver.

15. An organic light emissive device of claim 14, wherein the low workfunction metal is an alkali metal or an alkaline earth metal.

16. An organic light emissive device of claim 15, wherein the low workfunction metal is barium.

17. An organic light emissive device of claim 14, wherein the bilayer has a thickness in the range of from 5 nm to 20 nm.

18. An organic light emissive device of claim 14, wherein the bilayer has a thickness in the range of from 5 nm to 10 nm.

19. An organic light emissive device of claim 14, wherein the layer of silver has a thickness in the range of from 2 nm to 18 nm.

20. An organic light emissive device of claim 14, wherein the bilayer has a transparency in the device of at least 60%.

21. An organic light emissive device of claim 14, wherein the layer of silver has a transparency of at least 65%.

22. An organic light emissive device of claim 14, which is a top-emitting device.

23. An organic light emissive device of claim 22, wherein the anode is reflective.

24. An organic light emissive device of claim 22, wherein the anode is provided on a substrate comprising a metal mirror.

25. An organic light emissive device of claim 23, wherein the substrate comprises an active matrix back plane.

26. An organic light emissive device of claim 14, wherein the organic light emissive region comprises subpixels of red, green and blue light emitting materials, and the cathode injects electrons into each subpixel.

27. An organic light emissive device of claim 14, wherein the organic light emissive region comprises a light emitting polymer or dendrimer.

28. A process for the manufacture of an organic light emissive device of claim 14, comprising the steps of:
providing a portion of the device comprising an anode and an organic light emissive region;
depositing a layer of a low workfunction metal having a work function of no more than 3.5 eV; and
depositing a transparent silver layer to form a transparent bilayer on the organic light emissive region.
